(19) United States
(12) Patent Application Publication
(10) Pub. No.: US 2024/0170334 A1
(43) Pub. Date: May 23, 2024

(54) SEMICONDUCTOR CHIPS, SEMICONDUCTOR PACKAGES, AND MANUFACTURING METHODS THEREOF

(71) Applicant: SK hynix Inc., Icheon-si Gyeonggi-do (KR)

(72) Inventor: Hyun Chul SEO, Icheon-si Gyeonggi-do (KR)

(73) Assignee: SK hynix Inc., Icheon-si Gyeonggi-do (KR)

(21) Appl. No.: 18/493,654

(22) Filed: Oct. 24, 2023

(30) Foreign Application Priority Data
Nov. 22, 2022 (KR) 10-2022-0156954
Jun. 22, 2023 (KR) 10-2023-0080682

(51) Int. Cl. H01L 21/78; H01L 21/268; H01L 21/56; H01L 23/00; H01L 23/13; H01L 23/31

(52) U.S. Cl. CPC H01L 21/78; H01L 21/268; H01L 21/565; H01L 23/13; H01L 23/3121; H01L 24/16; H01L 2224/16225

(57) ABSTRACT

There are provided a semiconductor chip, a semiconductor package, and manufacturing methods thereof. The semiconductor chip is manufactured by forming first modified regions in a semiconductor substrate along a first direction at a first depth, forming second modified regions in the semiconductor substrate along a second direction different from the first direction at a second depth different from the first depth, and dicing the semiconductor substrate into semiconductor chips using the first and second modified regions. The semiconductor package is manufactured to include such a diced semiconductor chip.

### CROSS-REFERENCE TO RELATED APPLICATIONS

The present application claims priority under 35 U.S.C. 119(a) to Korean Application No. 10-2022-0156954, filed on Nov. 22, 2022, and Korean Application No. 10-2023-0080682, filed on Jun. 22, 2023, in the Korean Intellectual Property Office, which are incorporated herein by references in their entirety.

### BACKGROUND

### 1. Technical Field

The present disclosure generally relates to a packaging technology and, more particularly, to semiconductor chips, semiconductor packages, manufacturing methods of a semiconductor chip, and manufacturing methods of a semiconductor package.

### 2. Related Art

Semiconductor packaging may include dicing a semiconductor substrate or semiconductor wafer into semiconductor chips. Dicing a semiconductor substrate or a semiconductor wafer may be performed by using laser light such as wafer laser sawing technique and stealth dicing technique. Semiconductor packaging may include disposing a semiconductor chip over a package substrate and forming a molding layer protecting the semiconductor chip.

### SUMMARY

In accordance with an embodiment of the present disclosure is a manufacturing method of a semiconductor chip. The manufacturing method may include: forming first modified regions in a semiconductor substrate along a first direction at a first depth; forming second modified regions in the semiconductor substrate along a second direction different from the first direction at a second depth different from the first depth; and dicing the semiconductor substrate into semiconductor chips using the first and second modified regions.

In accordance with an embodiment of the present disclosure is a manufacturing method of a semiconductor package. The manufacturing method may include: forming first modified regions in a semiconductor substrate along a first direction at a first depth; forming second modified regions in the semiconductor substrate along a second direction different from the first direction at a second depth different from the first depth; dicing the semiconductor substrate into semiconductor chips using the first and second modified regions, each of the semiconductor chips including a first side surface diced along the first direction and a second side surface diced along the second direction; mounting a semiconductor chip of the semiconductor chips over a package substrate; and forming a molding layer covering the semiconductor chip by providing a molding material over the package substrate to flow toward the second side surface of the semiconductor chip.

In accordance with an embodiment of the present disclosure is a manufacturing method of a semiconductor package. The method includes disposing a semiconductor chip over a package substrate, and forming a molding layer covering the semiconductor chip. The semiconductor chip may include: a first surface and a second surface that are opposite to each other; a first side surface and a second side surface that extend from the first surface to the second surface; first modified regions located on the first side surface at a first distance from the first surface; and second modified regions located on the second side surface at a second distance from the first surface different from the first distance from the first surface. The molding layer may be formed by providing a molding material on the package substrate to flow toward the second side surface of the semiconductor chip.

In accordance with an embodiment of the present disclosure is a semiconductor chip including: a semiconductor substrate including a first surface and a second surface that are opposite to each other; a first side surface and a second side surface that extend from the first surface to the second surface; first modified regions located on the first side surface at a first distance from the first surface; and second modified regions located on the second side surface at a second distance from the first surface different from the first distance from the first surface.

In accordance with an embodiment of the present disclosure is a semiconductor package including a package substrate, a semiconductor chip disposed over the package substrate, and a molding layer covering the semiconductor chip. The semiconductor chip may include a semiconductor substrate including: a first surface and a second surface that are opposite to each other; a first side surface and a second side surface that extend from the first surface to the second surface; first modified regions located on the first side surface at a first distance from the first surface; and second modified regions located on the second side surface at a second distance from the first surface different from the first distance from the first surface.

### BRIEF DESCRIPTION OF THE DRAWINGS

FIG. 1 is a flowchart illustrating a manufacturing method of a semiconductor chip according to an embodiment of the present disclosure.

FIGS. 2 to 8 are views illustrating a manufacturing method of a semiconductor chip according to an embodiment of the present disclosure.

FIG. 9 is a perspective view illustrating a semiconductor chip according to an embodiment of the present disclosure.

FIGS. 10 to 14 are views illustrating a manufacturing method of a semiconductor package according to an embodiment of the present disclosure.

FIGS. 15 to 19 are views illustrating effects of a manufacturing method of a semiconductor package according to an embodiment of the present disclosure.

FIGS. 20 and 21 are views illustrating a semiconductor package according to an embodiment of the present disclosure.

FIG. 22 is a view illustrating effects of a manufacturing method of a semiconductor package according to an embodiment of the present disclosure.

### DETAILED DESCRIPTION

The terms used herein may correspond to words selected in consideration of their functions in presented embodiments, and the meanings of the terms may be construed to be different according to one of ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

In the description of the present disclosure, descriptions such as “first” and “second,” “side,” “top,” and “bottom” or “lower” are for distinguishing elements, and are not used to limit the elements themselves or to imply a specific order. In the description of the present disclosure, descriptions such as “on” or “under or beneath” mean a relative positional relationship, but do not limit the specific case in which another member is further introduced to the interface or in direct contact with the element. The same interpretation can be applied to other expressions describing the relationship between components.

Same reference numerals refer to same devices throughout the specification. Even though a reference numeral might not be mentioned or described with reference to a drawing, the reference numeral may be mentioned or described with reference to another drawing. In addition, even though a reference numeral might not be shown in a drawing, it may be shown in another drawing.

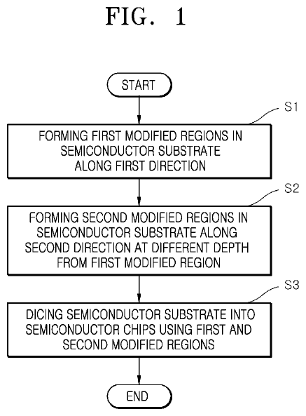

FIG. 1 is a flow chart illustrating process steps of a manufacturing method of a semiconductor chip according to an embodiment of the present disclosure.

Referring to FIG. 1, the manufacturing method of a semiconductor chip may include a method of dicing a semiconductor substrate using laser light. The manufacturing method of a semiconductor chip may include a stealth dicing technique. The manufacturing method of a semiconductor chip may include a step of forming first modified regions in the semiconductor substrate along a first direction (S1), a step of forming second modified regions in the semiconductor substrate along a second direction different from the first direction in a depth different from that of the first modified regions (S2), and a step of dicing the semiconductor substrate into semiconductor chips using the first and second modified regions (S3).

The step of dicing the semiconductor substrate into semiconductor chips (S3) may be performed such that cracks accompanying the first modified regions and the second modified regions are grown to reach first and second surfaces of the semiconductor substrate and the semiconductor chips are separated from the semiconductor substrate by the growth of the cracks. As the first modified regions and the second modified regions are formed in the semiconductor substrate, the cracks may be formed from the first and second modified regions and/or around the first and second modified regions. The semiconductor substrate may be expanded in a lateral direction to cause the cracks to grow or propagate, and the semiconductor chips may be separated from the semiconductor substrate by the growth of the cracks. An external force may be applied to the second surface of the semiconductor substrate for the growth or propagation of the cracks. The second surface of the semiconductor substrate may be grinded with a grinder, so that an external force that helps the growth of the cracks may be applied to the semiconductor substrate while reducing the thickness of the semiconductor substrate.

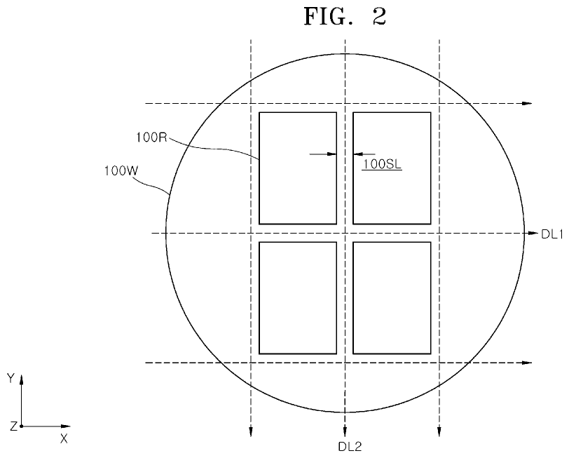

FIGS. 2 to 8 are views illustrating a manufacturing method of a semiconductor chip according to an embodiment of the present disclosure.

FIG. 2 is a plan view illustrating a semiconductor substrate 100W. Referring to FIG. 2, the semiconductor substrate 100W may include chip regions 100R and a scribe lane region 100SL. The semiconductor substrate 100W may have a shape of a wafer. When viewed from an X-Y plane, a plurality of chip regions 100R may be arranged in an X-axis direction and a plurality of chip regions 100R may be arranged in a Y-axis direction on the semiconductor substrate 100W. The chip regions 100R may be regions in which integrated circuits are integrated. The scribe lane region 100SL may be a region located between the chip regions 100R. The scribe lane region 100SL may be a region substantially excluding the integrated circuits.

The semiconductor substrate 100W may be diced so that each of the semiconductor chips includes the chip region 100R. Dicing lines separating the semiconductor chips from the semiconductor substrate 100W may be set. The dicing lines may be set to pass between the chip regions 100R. A first dicing line DL1 may extend in a first direction within the scribe line region 100SL. The first direction may be the X-axis direction in the X-Y-Z coordinate system. A second dicing line DL2 may cross the first dicing line DL1 in the scribe lane region 100SL. The second dicing line DL2 may extend in a second direction within the scribe line region 100SL. The second direction may be the Y-axis direction in the X-Y-Z coordinate system.

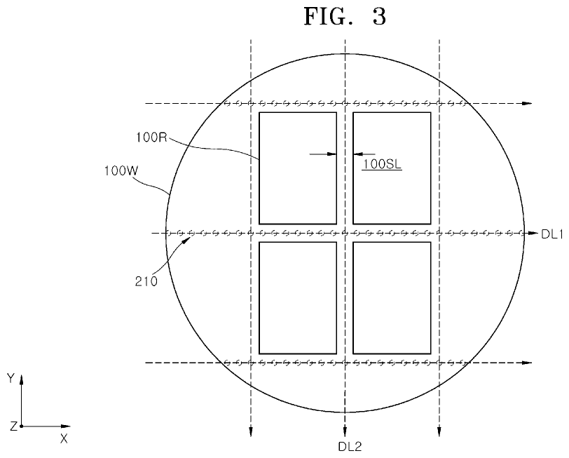

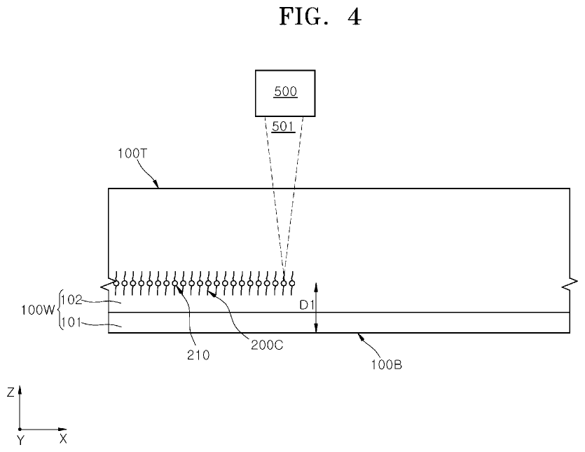

FIGS. 3 and 4 are views illustrating a step of forming first modified regions 210 in the semiconductor substrate 100W of FIG. 2. FIG. 4 may show a cross-sectional shape of the semiconductor substrate 100W along the first dicing line DL1 of FIG. 3. Referring to FIGS. 3 and 4, the first modified regions 210 may be formed in the semiconductor substrate 100W along the first direction in which the first dicing line DL1 extends.

The semiconductor substrate 100W may include first surface 100B and second surface 100T that are opposite to each other. The semiconductor substrate 100W may be a substrate or a wafer on which integrate circuits (ICs) are integrated. The integrated circuits may be integrated in the chip regions 100R of the semiconductor substrate 100W. The integrated circuits may include memory devices such as a dynamic random-access memory (DRAM) device, a static random-access memory (SRAM) device, a NAND flash memory device, a NOR flash memory device, a magnetic RAM (MRAM) device, a resistive RAM (ReRAM) device, a ferroelectric RAM (FeRAM) device, or a phase change RAM (PcRAM) device. Alternatively, the integrated circuits may constitute a logic circuit, an application processor (AP), a graphic processing unit (CPU), or a central processing unit (CPU).

The semiconductor substrate 100W may include a semiconductor base 102 and an active layer 101. The first modified regions 210 may be formed in the semiconductor base 102. The semiconductor base 102 may provide the second surface 100T of the semiconductor substrate 100W, and the active layer 101 may provide the first surface 100B. The semiconductor base 102 may be a body of the semiconductor substrate 100W. The semiconductor base 102 may include a semiconductor material. The semiconductor material may include silicon (Si). Some components constituting the integrated circuits may be formed in the semiconductor base 102. Impurity doped regions may be formed in the semiconductor base 102. The impurity doped regions may be formed in the semiconductor base 102 to configure electronic components such as transistors. The active layer 101 may include some other components constituting the integrated circuits. The active layer 101 may include various types of conductive patterns, dielectric layers, and insulating layers. The conductive patterns may be formed to configure word lines, bit lines, or wirings of a memory device.

The first modified regions 210 may be formed by irradiating laser light 501 into the semiconductor substrate 100W. The first modified regions 210 may be formed in the semiconductor base 102 of the semiconductor substrate 100W by applying a stealth dicing technique. The first modified regions 210 may be formed within the scribe lane region 100SL. The laser light 501 may be irradiated into the semiconductor substrate 100W through the second surface 100T of the semiconductor substrate 100W. The laser light 501 may be generated by a laser light source 500.

The laser light source 500 may radiate the laser light 501 into the semiconductor substrate 100W so that the laser light 501 is focused on the semiconductor base 102 at a predetermined depth. Some portions of the semiconductor base 102 on which the laser light 501 is focused may be heated by the energy transferred from the laser light 501, and the crystal structures of the portions may be changed. The regions where the laser light 501 is focused may be deformed or modified to have a crystal structure different from that of the semiconductor base 102. The semiconductor base 102 may have a single crystalline structure, and the first modified region 210 may have a polycrystalline structure or an amorphous structure. The first modified region 210 may be formed to have a crystal structure different from that of the surrounding semiconductor base 102 regions. As the crystal structure of the first modified region 210 is formed differently from the surrounding semiconductor base 102, stress may be accompanied around the first modified regions 210, and cracks 200C may be caused by the stress. The cracks 200C may be generated from the first modified regions 210, or may be generated around the first modified regions 210.

The laser light 501 may be repeatedly irradiated into the semiconductor substrate 100W along the first direction in which the first dicing line DL1 extends. While moving the position of the laser light source 500 and/or the position of the semiconductor substrate 100W along the first direction, the laser light 501 may be repeatedly irradiated into the semiconductor substrate 100W. Accordingly, the first modified regions 210 arranged along the first direction may be formed. The first modified regions 210 may be spaced apart from each other by a certain distance in the first direction or the X-axis direction. The first modified regions 210 may be formed to have substantially the same depth in the Z-axis direction within the semiconductor base 102 of the semiconductor substrate 100. The Z-axis direction may be a thickness direction of the semiconductor substrate 100W, or may be a direction perpendicular to the first and second surfaces 100B and 100T of the semiconductor substrate 100W. The first modified regions 210 may be spaced apart from the first surface 100B of the semiconductor substrate 100W by a first distance D1 in the Z-axis direction. The first modified regions 210 may be spaced apart from the active layer 101 by a certain distance in the Z-direction.

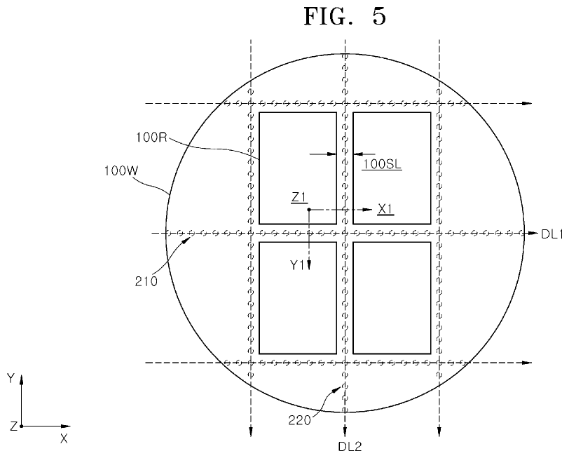

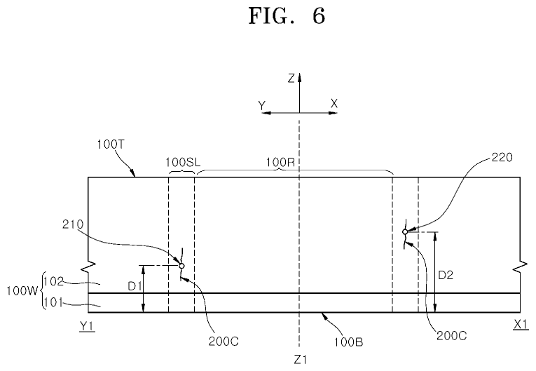

FIGS. 5 and 6 are views illustrating a step of forming the second modified regions 220 in the semiconductor substrate 100W. FIG. 6 shows a cross-sectional shape along a cutting line Y1-Z1-X1 of FIG. 5.

Referring to FIGS. 5 and 6, the second modified regions 220 may be formed in the semiconductor substrate 100W along the second direction in which the second dicing line DL2 extends. The second modified regions 220 may be formed within the scribe lane region 100SL. The laser light may be irradiated into the semiconductor substrate 100W from the second surface 100T of the semiconductor substrate 100W. As portions where the laser light is focused may be modified, the second modified regions 220 may be formed in the semiconductor substrate 100W. By repeatedly irradiating the laser light along the second direction, the second modified regions 220 may be formed to be arranged along the second direction. The second modified region 220 may be formed to have a crystal structure different from that of the surrounding semiconductor base 102 regions. The second modified region 220 may have a crystal structure different from that of the semiconductor base 102. As the second modified regions 220 are formed, the cracks 200C may be generated around the second modified regions 220.

The first modified regions 210 and the second modified regions 220 may be formed in the semiconductor base 102 of the semiconductor substrate 100W at different depths from each other. The first modified regions 210 and the second modified regions 220 may be located at different distances from each other, from the first surface 100B or the second surface 100T of the semiconductor substrate 100W. The second modified regions 220 may be spaced apart from the first surface 100B of the semiconductor substrate 100W by a second distance D2 in the Z-axis direction. The second distance D2 may be farther than the first distance D1. The first modified regions 210 may be located closer to the first surface 100B of the semiconductor substrate 100W than the second modified regions 220. The first modified regions 210 may be located closer to the active layer 101 of the semiconductor substrate 100W than the second modified regions 220. The second modified regions 220 may be located farther from the active layer 101 of the semiconductor substrate 100W than the first modified regions 210. The second modified regions 220 may be formed at an intermediate portion, based on the thickness direction of the semiconductor base 102.

Although the second modified regions 220 may be formed after the first modified regions 210 are formed, the manufacturing method of a semiconductor chip according to an embodiment of the present disclosure is not limited thereto. The second modified regions 220 may be formed first, and then the first modified regions 210 may be formed.

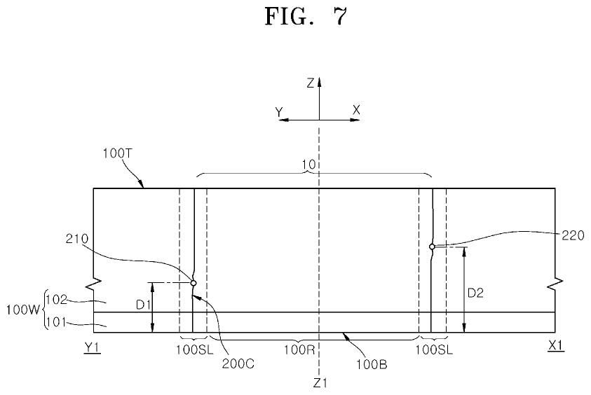

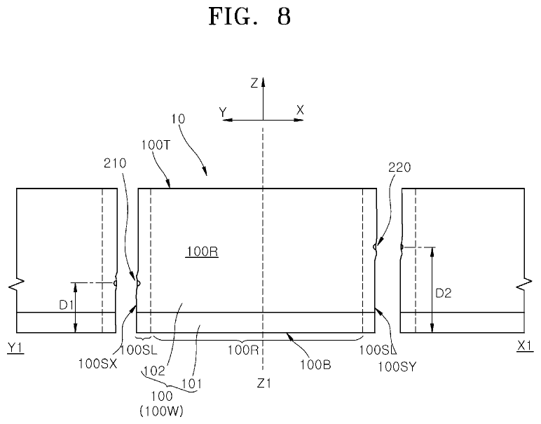

FIGS. 7 and 8 are cross-sectional views illustrating a step of dicing the semiconductor substrate 100W. FIGS. 7 and 8 may show cross-sectional shapes along the cutting line Y1-Z1-X1 of FIG. 5. Referring to FIGS. 7 and 8, the semiconductor substrate 100W may be diced into semiconductor chips 10 using the first modified regions 210 and the second modified regions 220.

More specifically, the cracks 200C may be grown by applying an external force to the semiconductor substrate 100W. The cracks 200C may be propagated across the semiconductor substrate 100W. The cracks 200C may be grown in the Z-axis direction within the semiconductor substrate 100W.

To grow the cracks 200C, a load may be applied to the second surface 100T of the semiconductor substrate 100W. Alternatively, the semiconductor substrate 100W may be expanded in an outward circumferential direction. The cracks 200C may be grown by pulling the semiconductor chip 100W in the X-axis direction and the Y-axis direction. Although not shown, an expanding tape may be attached to the semiconductor substrate 100W and the expanding tape may be pulled and expanded, thereby expanding the semiconductor substrate 100W.

When the cracks 200C are grown to the first and second surfaces 100B and 100T of the semiconductor substrate 100W, the semiconductor substrate 100W may be diced along the grown cracks 200C. Accordingly, as shown in FIG. 8, the semiconductor chips 10 may be separated from the semiconductor substrate 100W. Each of the semiconductor chips 10 may include the chip region 100R and a portion of the scribe lane region 100SL.

The cracks 200C may be grown to the first and second surfaces 100B and 100T of the semiconductor substrate 100W to form dicing surfaces 100SX and 100SY. The dicing surfaces 100SX and 100SY may be side surfaces 100SX and 100SY of the semiconductor chip 10. The first dicing surface 100SX diced in the X-axis direction may be the first side surface 100SX of the semiconductor chip 10. The second dicing surface 100SY diced in the Y-axis direction may be the second side surface 100SY of the semiconductor chip 10. The first and second side surfaces 100SX and 100SY of the semiconductor chip 10 may be orthogonal to each other.

In this way, because the cracks 200C generate the dicing surfaces 100SX and 100SY, and the dicing surfaces 100SX and 100SY constitute the first and second side surfaces 100SX and 100SY of the semiconductor chip, the first modified regions 210 may remain on the first side surface 100SX of the semiconductor chip 10, and the second modified regions 220 may remain on the second side surface 100SY. Alternatively, a portion of the first modified regions 210 may remain on the first side surface 100SX of the semiconductor chip 10, and a portion of the second modified regions 220 may remain on the second side surface 100SY.

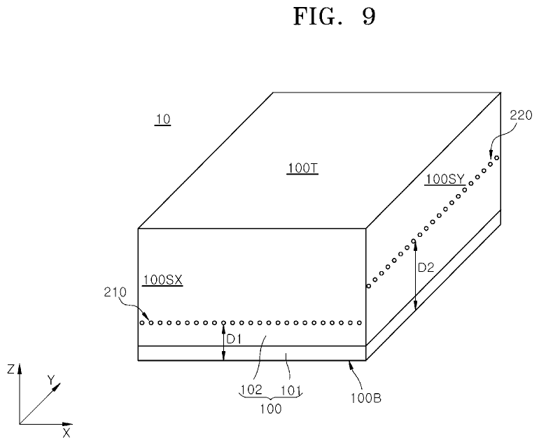

FIG. 9 is a perspective view illustrating a semiconductor chip 10 according to an embodiment of the present disclosure. Referring to FIG. 9, the semiconductor chip 10 may have a first surface 100B and a second surface 100T that are apposite to each other, a first side surface 100SX, and a second side surface 100SY. The first side surface 100SX and the second side surface 100SY may be dicing surfaces extending from the first surface 100B to the second surface 100T.

First modified regions 210 may be located on the first side surface 100SX, and second modified regions 220 may be located on the second side surface 100SY. The first modified regions 210 and the second modified regions 220 may be located at different distances D1 and D2 from the first surface 100B of a semiconductor substrate 100. The first modified regions 210 may be located closer to the first surface 100B than the second modified regions 220. The semiconductor substrate 100 may include a semiconductor base 102 and an active layer 101, and each of the first modified regions 210 and the second modified regions 220 may have a crystal structure different from that of the semiconductor base 102.

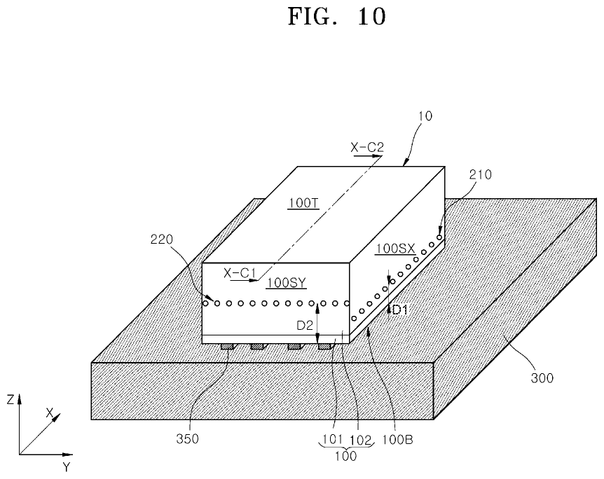

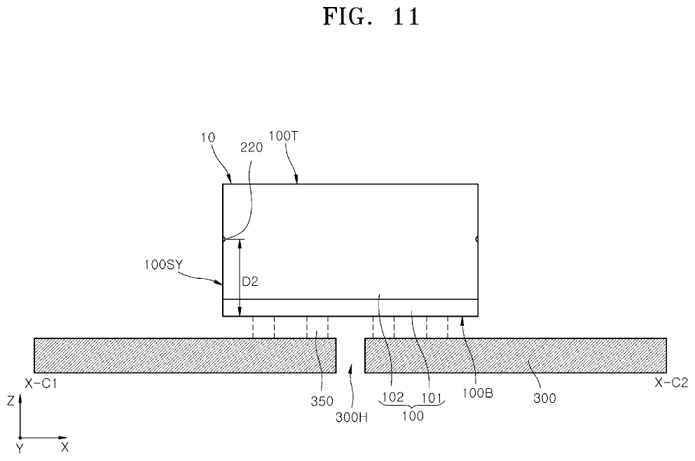

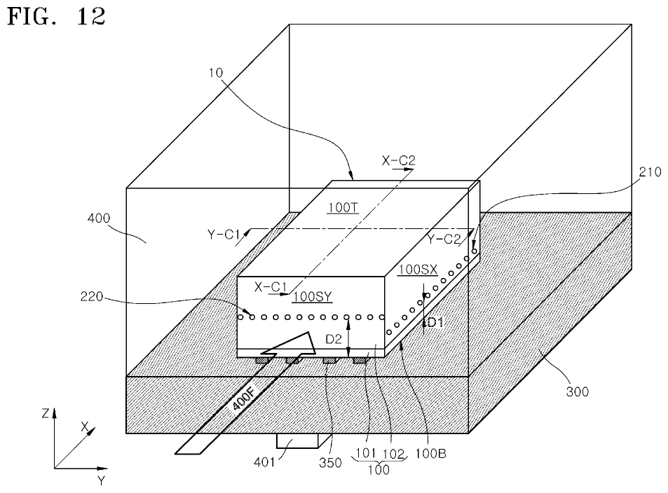

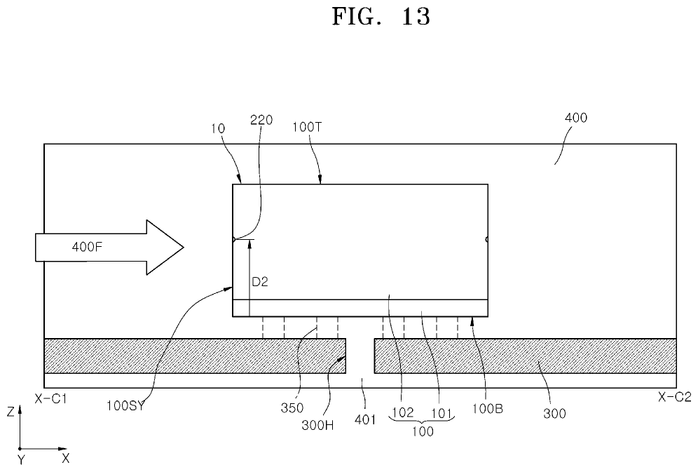

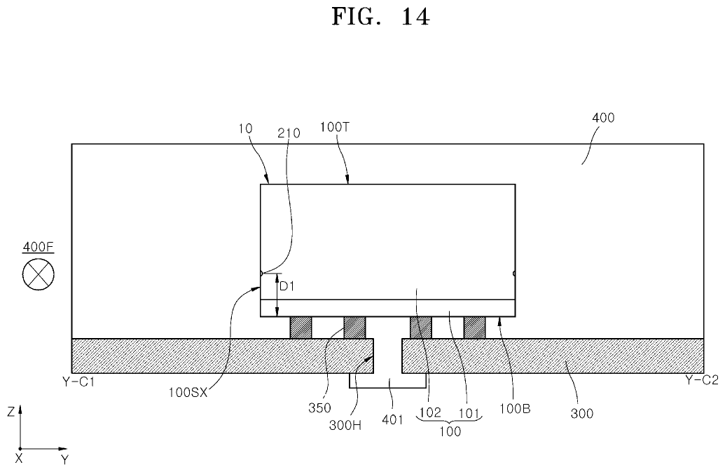

FIGS. 10 to 14 are views illustrating a manufacturing method of a semiconductor package according to an embodiment of the present disclosure. FIG. 11 shows a cross-sectional shape along a line X-C1˜X-C2 of FIG. 10. The cutting line X-C1˜X-C2 may be a cross-sectional line passing through a center of a semiconductor chip 10 in the X-axis direction. FIG. 13 may show a cross-sectional shape along the cutting line X-C1˜X-C2 of FIG. 12. FIG. 14 may show a cross-sectional shape along a cutting line Y-C1˜Y-C2 of FIG. 12. The cutting line Y-C1˜Y-C2 may be a cross-sectional line passing through the center of the semiconductor chip 10 in the Y-axis direction.

Referring to FIGS. 10 and 11, the semiconductor chip 10 may be mounted over a package substrate 300. The semiconductor chip 10 may be prepared using the manufacturing method as described in FIGS. 1 to 8. Specifically, as shown in FIGS. 3 and 4, first modified regions 210 may be formed in a semiconductor substrate 100W along a first direction. As shown in FIGS. 5 and 6, second modified regions 220 may be formed in the semiconductor substrate 100W along a second direction at a depth different from that of the first modified regions 210. As shown in FIGS. 7 and 8, the semiconductor substrate 100W may be diced into the semiconductor chips 10 using the first and second modified regions 210 and 220. The semiconductor chip 10 may include a first side surface 100SX, and a second side surface 100SY orthogonal to the first side surface 100SX. The first modified regions 210 may remain on the first side surface 100SX, and the second modified regions 220 may remain on the second side surface 100SY.

The semiconductor chip 10 may be disposed over the package substrate 300 such that the first surface 100B of the diced semiconductor substrate 100 faces the package substrate 300. The semiconductor chip 10 may be disposed over the package substrate 300 such that the active layer 101 of the semiconductor substrate 100 faces the package substrate 300. The semiconductor chip 10 may be connected to the package substrate 300 by conductive connectors 350. The conductive connectors 350 may be conductive bumps.

The package substrate 300 may be a printed circuit board (PCB). Alternatively, the package substrate 300 may be an interposer. The package substrate 300 may include wirings electrically connecting the semiconductor chip 10 to an external device or another electronic device. The package substrate 300 may further include a through hole 300H at a position where the semiconductor chip 10 overlaps.

Referring to FIGS. 12, 13, and 14, a molding layer 400 covering the semiconductor chip 10 may be formed. Specifically, a molding process may be performed on the package substrate 300 on which the semiconductor chip 10 is mounted. The package substrate 300 may be mounted in a mold, and a molding material may be injected into the mold. The molding layer 400 may be formed by covering the semiconductor chip 10 with the molding material.

A flow 400F of the molding material flowing into the mold to cover the semiconductor chip 10 may be formed from an injection hole through which the molding material is injected into the mold. The flow 400F of the molding material may be formed so that the molding material flows toward the second side surface 100SY of the semiconductor chip 10. The semiconductor chip 10 may be disposed over the package substrate 300 such that an injection hole of the mold into which the molding material is injected faces the second side surface 100SY of the semiconductor chip 10. Accordingly, the flow 400F of the molding material may be induced so that the molding material flows toward the second side surface 100SY of the semiconductor chip 10.

By the flow 400F of the molding material, the molding layer 400 may further extend to fill a space between the semiconductor chip 10 and the package substrate 300. Vacuum from the bottom of the mold may be applied through the through hole 300H. The through hole 300H may be a vent hole for air ventilation. Due to a pressure by the injection of the molding material into the mold and/or a pressure difference caused by the vacuum through the through hole 300H, the molding material may flow between the semiconductor chip 10 and the package substrate 300 and fill the space between the semiconductor chip 10 and the package substrate 300. The molding material may be introduced into the through hole 300H to fill the through hole 300H, and thus, the molding layer 400 may extend to form the molding layer bottom portion 401 protruding from the package substrate 300 while filling the through hole 300H. The molding layer bottom portion 401 may be formed in a bar shape or a linear shape extending in substantially the same direction as the direction of the flow 400F of the molding material. Because the flow 400F of the molding material is formed toward the second side surface 100SY of the semiconductor chip 10, the molding layer bottom portion 401 may have a bar shape extending in a plane direction perpendicular to the second side surface 100SY of the semiconductor chip 10, that is, in an X-axis direction.

As such, a semiconductor package including the semiconductor chip 10 mounted over the package substrate 300 and the molding layer 400 covering the semiconductor chip 10 may be formed.

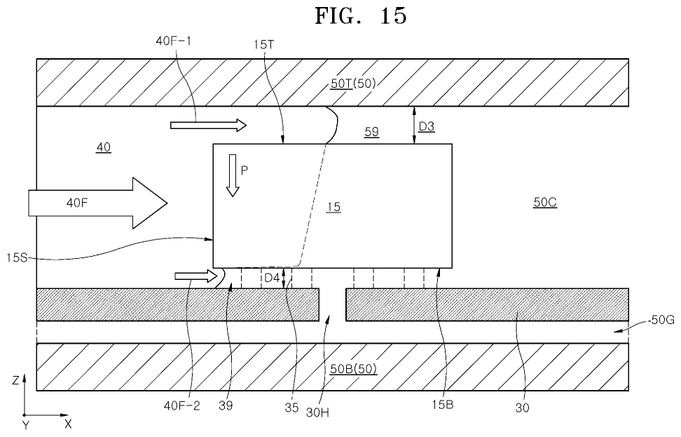

FIGS. 15 to 19 are views illustrating effects of a manufacturing method of a semiconductor package according to an embodiment of the present disclosure.

Referring to FIG. 15, a semiconductor chip 15 may be mounted over a package substrate 30 using conductive connectors 35, and a molding material may flow onto the package substrate 30 to form a molding layer 40. Specifically, the package substrate 30 may be mounted in a mold 50, and a molding material may be injected into the mold 50. The mold 50 includes an upper mold 50T and a lower mold 50B. The upper mold 50T may be introduced over the semiconductor chip 15 to form a cavity 50C. The molding material may be filled in the cavity 50C, that is, formed between the package substrate 30 and the upper mold 50T. The lower mold 50B may have a molding groove 50G in which the molding layer bottom portion 401 of FIGS. 13 and 14 is molded. The lower mold 50B may contact the package substrate 30, and the molding groove 50G may be formed as an empty space between the package substrate 30 and the lower mold 50B.

The flow 40F of the molding material occurs when the molding material in the cavity 50C flowing from one edge of the package substrate 30 to an opposite edge. The molding material may be injected into the cavity 50 such that the molding material flows toward a side surface 15S of the semiconductor chip 15.

Referring to FIG. 15, due to the flow 40F of the molding material, a first flow 40F-1 of the molding material covering a second surface 15T, which is an upper surface of the semiconductor chip 15, and a second flow 40F-2 of the molding material flowing into a space 39 between the package substrate 30 and a first surface 15B, which is a lower surface of the semiconductor chip 15 may be induced.

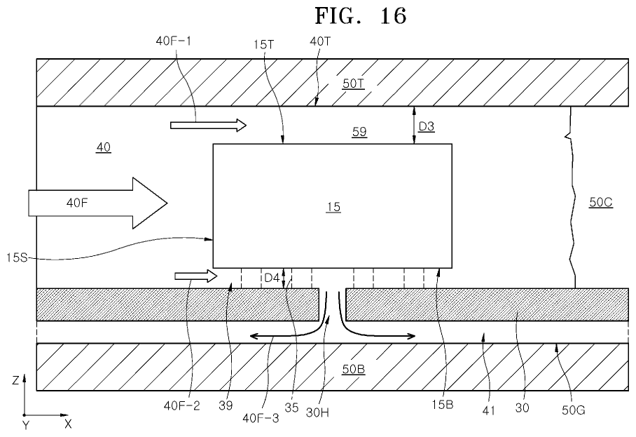

Referring to FIG. 16, the first flow 40F-1 of the molding material may further proceed so that the molding material completely covers the semiconductor chip 15. The second flow 40F-2 of the molding material may further proceed so that the molding material fills the space 39. The molding material flowing into the space 39 may flow into a through hole 300H by vacuum, and further flow into the molding groove 50G of the lower mold 50B. By a third flow 40F-3 of the molding material, the molding material may pass through the through hole 300H and fill the molding groove 50G of the lower mold 50B. As the molding material fills the molding groove 50G of the lower mold 50B, the molding layer bottom portion 41 may be formed. Because the molding groove 50G of the lower mold 50B has a trench shape extending in the direction of the flow 40F of the molding material, the molding layer bottom portion 41 may be a long linear shape or a bar shape.

Referring back to FIG. 15, the first flow 40F-1 of the molding material may show a relatively higher flow rate than the second flow 40F-2 of the molding material. When the package substrate 30 is mounted in the mold 50, the second surface 15T of the semiconductor chip 15 and the upper mold 50T may be substantially vertically spaced apart by a first separation distance D3. The first surface 15B of the semiconductor chip 15 and the package substrate 30 may be substantially vertically spaced apart by a second separation distance D4. Because the second separation distance D4 depends on the height or thickness of the conductive connector 35, the second separation distance D4 may be substantially the same as the height or thickness of the conductive connector 35. The first separation distance D3 between the upper mold 50T and the semiconductor chip 15 may be greater than the second separation distance D4 between the semiconductor chip 15 and the package substrate 30 by the conductive connector 35.

Because the first separation distance D3 is greater than the second separation distance D4, a space 59 between the second surface 15T of the semiconductor chip 15 and the upper mold 50T may be greater than a space 39 between the first surface 15B of the semiconductor chip 15 and the package substrate 30. The first flow 40F-1 of the molding material flowing into the space 59 may represent a relatively higher flow rate than the second flow 40F-2 of the molding material.

Accordingly, before the space 39 is filled with the molding material, a portion of the second surface 15T of the semiconductor chip 15 overlapping the space 39 may be covered with the molding material. Due to the difference in flow rate of the molding material flows 40F-1 and 40F-2, a pressure P may be applied to the semiconductor chip 15 in a direction from the second surface 15T toward the first surface 15B. The pressure P may be locally applied to a portion adjacent to the side surface 15S of the semiconductor chip 15. Due to the difference in flow rate between the flows 40F-1 and 40F-2 of the molding material, the pressure P may be applied from an upper portion of the semiconductor chip 15 to a bottom of the semiconductor chip 15. The upper portion of the semiconductor chip 15 may be covered faster than the bottom of the semiconductor chip 15 by the molding material later. Stress may be locally applied on the semiconductor chip 15. When the semiconductor chip 15 is not strong enough to withstand the stress, cleavage may occur in the semiconductor chip 15. It can be observed that the cleavage starts from a portion adjacent to the side surface 15S of the semiconductor chip 15 that is first covered with the molding material. The cleavage may propagate in the direction in which the molding material flows.

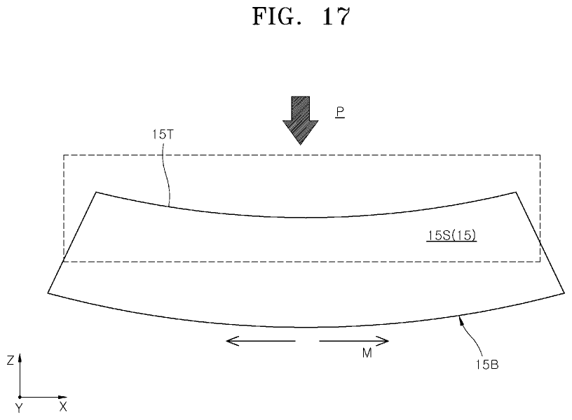

Referring to FIGS. 15 and 17, the pressure P generated on the portion adjacent to the side surface 15S of the semiconductor chip 15 may act as a force that bends the portion adjacent to the side surface 15S of the semiconductor chip 15. The pressure P may induce tensile stress M in a portion of the first surface 15B of the semiconductor chip 15 facing the package substrate 30. The tensile stress M may be a force directed from the center portion to the edge portions of the semiconductor chip 15 when viewed in the X-axis direction. Because the pressure P may be locally limited to the portion adjacent to the side surface 15S of the semiconductor chip 15, the tensile stress M may also be locally limited to the portion adjacent to the side surface 15S of the semiconductor chip 15.

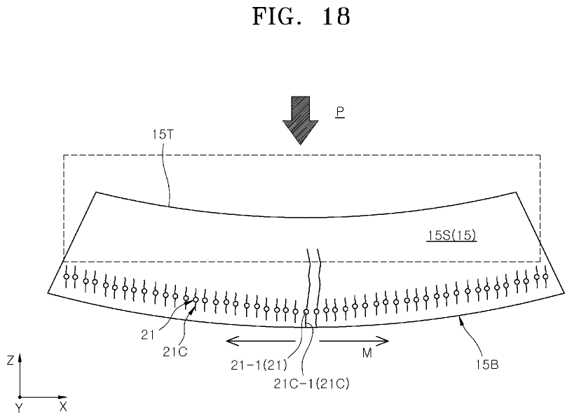

Referring to FIGS. 17 and 18, when portions of the first modified regions 21 for dicing the semiconductor chip 15 remain on the side surface 15S, the cracks 21C may additionally grow or propagate from the residue of the first modified regions 21 by the tensile stress M. The cleavage may be induced in the semiconductor chip 15 by the growth of these cracks 21C. Because the tensile stress M may be locally concentrated on the central portion of the semiconductor chip 15, the cracks 21C-1 may relatively preferentially grow from the first modified regions 21-1 located in the central portion of the semiconductor chip 15. When the cracks 21C-1 reach the first surface 15B of the semiconductor chip 15, the cleavage may be generated in the semiconductor chip 15.

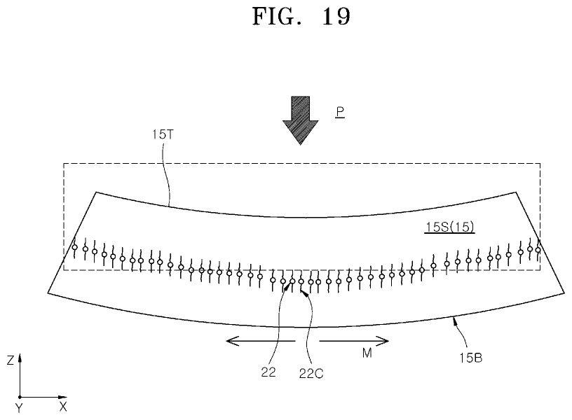

Referring to FIGS. 18 and 19, when the first modified regions 21 are located closer to the first surface 15B than the second modified regions 22, the first modified regions 21 may be more strongly affected by the tensile stress M than the second modified regions 22. Accordingly, when the same pressure P is applied, the probability of the cracks 21C growing into the cleavage from the first modified regions 21 may be higher than the probability of the cracks 22C growing into the cleavage from the second modified regions 22. The semiconductor chip 15 in which the second modified regions 22 located farther from the first surface 15B than the first modified regions 21 are located on the side surface 15S may show relatively increased chip strength.

Referring back to FIG. 12, in the method of manufacturing the semiconductor package according to an embodiment of the present disclosure, the semiconductor chip 10 may be disposed over the package substrate 300 so that the second side surface 100SY faces the flow 400F of the molding material, and the molding material may be provided onto the package substrate 300 so as to flow toward the second side surface 100SY. The second modified regions 220 remaining on the second side surface 100SY may be located farther from the first surface 100B than the first modified regions 210. Accordingly, by the local pressure P generated by the difference between the flows 40F-1 and 40F-2 of the molding material as shown in FIG. 15, it is possible to reduce or suppress the cleavage caused by the growth of the cracks 21C-1 in the semiconductor chip 10 as shown in FIG. 18.

In this way, the generation of the cleavage in the semiconductor chips 10 may be reduced or suppressed in the process of forming the molding layer 400 by controlling the flow 400F of the molding material and the arrangement direction of the semiconductor chips 10. Breakage or damage of the semiconductor chips 10 may be reduced.

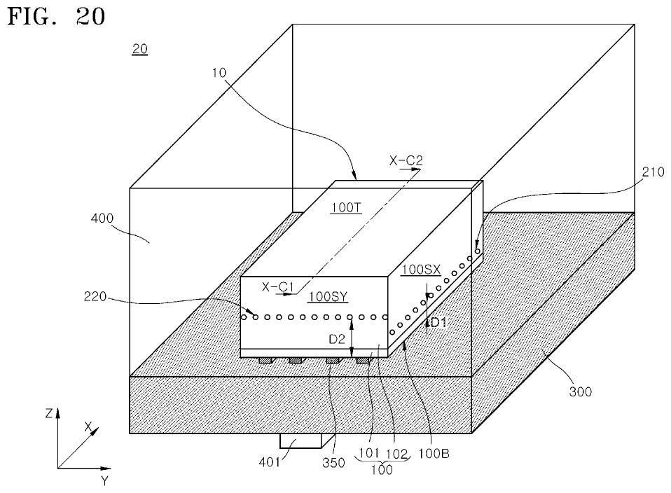

FIG. 20 is a view illustrating a semiconductor package 20 according to an embodiment of the present disclosure. Referring to FIG. 20, the semiconductor package 20 may include a semiconductor chip 10 disposed over a package substrate 300, and a molding layer 400 covering the semiconductor chip 10. The semiconductor chip 10 may include a semiconductor substrate 100, and the semiconductor substrate 100 may include first and second surfaces 100B and 100T opposite to each other, and first and second side surfaces 100SX and 100SY extending from the first surface 100B to the second surface 100T. First modified regions 210 may be located on the first side surface 100SX, and second modified regions 220 may be located on the second side surface 100SY. The first modified regions 210 and the second modified regions 220 may be located at different distances D1 and D2 from the first surface 100B. The molding layer 400 may further extend between the semiconductor chip 10 and the package substrate 300. The package substrate 300 further includes a through hole (300H in FIG. 13) at a position where the semiconductor chip 10 overlaps, and the molding layer 400 may extend to form a molding layer bottom portion 401 protruding from the package substrate 300 while filling the through hole 300H.

Referring back to FIG. 16, an upper surface 40T of the molding layer 40 may be formed to contact a surface of an upper mold 50T. The first separation distance D3 between the upper mold 50T and the semiconductor chip 10 may be greater than the second separation distance D4 between the semiconductor chip 15 and the package substrate 30. Accordingly, the separation distance between the second surface 15T of the semiconductor chip 15 may be greater than the separation distance between the semiconductor chip 15 and the package substrate 30. A thickness of a portion of the molding layer 40 covering the second surface 15T of the semiconductor chip 15 may be greater than the separation distance between the semiconductor chip 15 and the package substrate 30.

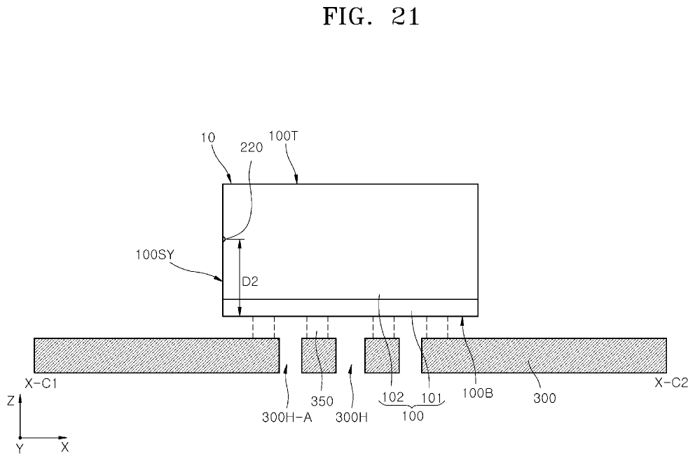

FIG. 21 is a view illustrating an example of a package substrate 300 of a semiconductor package according to an embodiment of the present disclosure. Referring to FIGS. 13 and 21, the package substrate 300 may include a through hole 300H, and the through hole 300H may be formed in the package substrate 300 to be overlapped with a central portion of a semiconductor chip 10. A through hole 300H-A may be formed in the package substrate 300 to be overlapped with a position away from the central portion of the semiconductor chip 10. The plurality of through holes 300H-A and 300H may be formed in the package substrate 300 to be disposed along one direction. The plurality of through holes 300H-A and 300H may be formed in the package substrate 300 along a virtual line X-C1˜X-C2 passing through the center of the semiconductor chip 10 or along the X-axis direction.

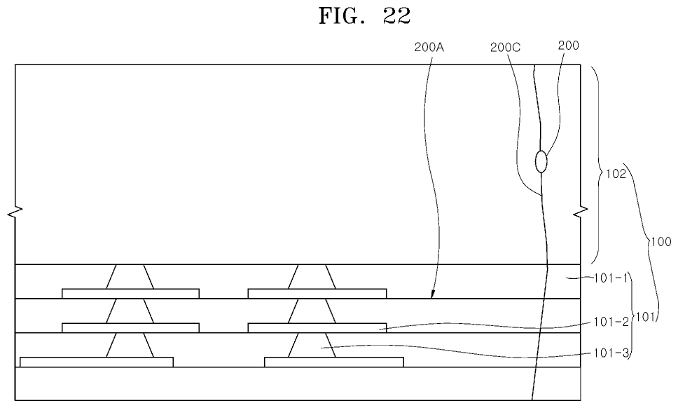

FIG. 22 is a view illustrating effects of a manufacturing method of a semiconductor package according to an embodiment of the present disclosure. Referring to FIG. 22, a semiconductor substrate 100 may include a semiconductor base 102 formed of single crystalline silicon (Si), and an active layer 101 formed on the semiconductor base 102. The active layer 101 may include a dielectric layer 101-1, a conductive pattern 101-2, and a conductive connector 101-3. A plurality of dielectric layers 101-1 may be stacked, and a plurality of conductive patterns 101-2 insulated by the dielectric layers 101-1 may be stacked. A plurality of conductive connectors 101-3 may connect the conductive patterns 101-2 to each other substantially vertically.

In this way, because the active layer 101 may include a plurality of layers, propagation of the crack 200C traversing the active layer 101 may be more difficult than in the semiconductor base 102 of single crystalline structure. At the interfaces 200A of the layers constituting the active layer 101, the progress of the crack 200C may be dispersed along the interfaces. Accordingly, the dicing force according to the progress of the crack 200C may be lowered. To improve the dicing force or to improve the propagation ability of the crack 200C, the modified region 200 may be located relatively close to the active layer 101.

According to a manufacturing method of a semiconductor chip according to an embodiment of the present disclosure, the first modified regions 210 may be formed closer to the active layer 101 or to the first surface 100B than the second modified regions 220 as shown in FIG. 7. Accordingly, it is possible to suppress the dicing force from being dispersed when the semiconductor substrate 100W is diced.

The inventive concept has been disclosed in conjunction with some embodiments as described above. Those skilled in the art will appreciate that various modifications, additions, and/or substitutions are possible, without departing from the scope and spirit of the present disclosure. Accordingly, the embodiments disclosed in the present specification should be considered from not a restrictive standpoint but an illustrative standpoint. The scope of the inventive concept is not limited to the above descriptions but defined by the accompanying claims, and all distinctive features in the equivalent scope should be construed as being included in the inventive concept.

What is claimed is:

1. A method of manufacturing a semiconductor chip, comprising:
forming first modified regions in a semiconductor substrate along a first direction at a first depth;
forming second modified regions in the semiconductor substrate along a second direction different from the first direction at a second depth different from the first depth; and
dicing the semiconductor substrate into semiconductor chips using the first and second modified regions.

2. The method of claim 1,
wherein the semiconductor substrate has a first surface and a second surface that are opposite to each other, and
wherein the first modified regions are located closer to the first surface than the second modified regions.

3. The method of claim 2, wherein the semiconductor substrate includes:
a semiconductor base providing the second surface; and
an active layer formed on the semiconductor base, the active layer provides the first surface.

4. The method of claim 1, wherein the first modified regions and the second modified regions include crystal structures different from crystal structures of the semiconductor substrate.

5. The method of claim 1, wherein dicing the semiconductor substrate includes:
growing cracks accompanying the first modified regions and the second modified regions to reach opposite surfaces of the semiconductor substrate; and
expanding the semiconductor substrate so that the semiconductor chips are separated from the semiconductor substrate by the cracks.

6. The method of claim 1, wherein the first modified regions are formed by irradiating laser light in the semiconductor substrate from the surface of the semiconductor substrate, and modifying portions of the semiconductor substrate where the laser light is focused, by the laser light.

7. The method of claim 1, wherein each of the semiconductor chips is separated from the semiconductor substrate to include a first side surface on which the first modified regions are located and a second side surface on which the second modified regions are located.

8. A method of manufacturing a semiconductor package, comprising:
forming first modified regions in a semiconductor substrate along a first direction at a first depth;
forming second modified regions in the semiconductor substrate along a second direction different from the first direction at a second depth different from the first depth;
dicing the semiconductor substrate into semiconductor chips using the first and second modified regions, each of the semiconductor chips including a first side surface diced along the first direction and a second side surface diced along the second direction;
mounting a semiconductor chip of the semiconductor chips over a package substrate; and
forming a molding layer covering the semiconductor chip by providing a molding material over the package substrate to flow toward the second side surface of the semiconductor chip.

9. The method of claim 8,
wherein the semiconductor substrate has a first surface and a second surface that are opposite to each other, and
wherein the first modified regions are located closer to the first surface than the second modified regions.

10. The method of claim 9, wherein the semiconductor chip is disposed over the package substrate such that the first surface faces the package substrate.

11. The method of claim 9, wherein the semiconductor substrate includes:
a semiconductor base providing the second surface; and
an active layer formed on the semiconductor base, the active layer provides the first surface.

12. The method of claim 8, wherein the first modified regions and the second modified regions include crystal structures different from a crystal structure of the semiconductor substrate.

13. The method of claim 8, wherein dicing the semiconductor substrate includes:
growing cracks accompanying the first modified regions and the second modified regions to reach opposite surfaces of the semiconductor substrate; and
expanding the semiconductor substrate so that the semiconductor chips are separated from the semiconductor substrate by the cracks.

14. The method of claim 8, wherein the first modified regions are formed by irradiating laser light in the semiconductor substrate from a surface of the semiconductor substrate, and modifying portions of the semiconductor substrate where the laser light is focused, by the laser light.

15. The method of claim 8, wherein the molding layer further extends between the package substrate and the semiconductor chip.

16. The method of claim 8,
wherein the package substrate further includes a through hole at a position overlapping the semiconductor chip, and
wherein the molding layer extends to fill the through hole.

17. The method of claim 8, wherein the semiconductor chip is connected to the package substrate by conductive connectors.

18. The method of claim 17,
wherein forming the molding layer includes:
mounting the package substrate in a mold; and
injecting the molding material into the mold, and
wherein a separation distance between the mold and the semiconductor chip is greater than a separation distance between the semiconductor chip and the package substrate.

19. A method of manufacturing a semiconductor package, comprising:
disposing a semiconductor chip over a package substrate; and
forming a molding layer covering the semiconductor chip,
wherein the semiconductor chip includes:
a first surface and a second surface that are opposite to each other;
a first side surface and a second side surface that extend from the first surface to the second surface;
first modified regions located on the first side surface at a first distance from the first surface; and
second modified regions located on the second side surface at a second distance from the first surface different from the first distance from the first surface, and
wherein the molding layer is formed by providing a molding material on the package substrate to flow toward the second side surface of the semiconductor chip.

20. A semiconductor chip comprising a semiconductor substrate, the semiconductor substrate including:
a first surface and a second surface that are opposite to each other;
a first side surface and a second side surface that extend from the first surface to the second surface;
first modified regions located on the first side surface at a first distance from the first surface; and
second modified regions located on the second side surface at a second distance from the first surface different from the first distance from the first surface.

21. The semiconductor chip of claim 20, wherein the semiconductor substrate further includes:
a semiconductor base providing the second surface; and
an active layer formed on the semiconductor base, the active layer providing the first surface.

22. The semiconductor chip of claim 20, wherein the first modified regions and the second modified regions have crystal structures different from a crystal structure of the semiconductor substrate.

23. The semiconductor chip of claim 20, wherein the first modified regions are located closer to the first surface than the second modified regions.

24. The semiconductor chip of claim 20, wherein the first side surface and the second side surface are side surfaces crossing each other.
